(19) United States
(12) Patent Application Publication
(10) Pub. No.: US 2007/0211522 A1
(43) Pub. Date: Sep. 13, 2007

(54) Magnetic random access memory

(76) Inventors: Yoshiaki Fukuzumi, Yokohama-shi (JP); Tadashi Kai, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/455,644

(22) Filed: Jun. 20, 2006

(30) Foreign Application Priority Data
Mar. 13, 2006 (JP) 2006-067963

(51) Int. Cl. G11C 11/00; G11C 5/08

(52) U.S. Cl. 365/158; 365/66

(57) ABSTRACT

A magnetic random access memory according to an embodiment of the present invention comprises first and second write lines which cross each other, and a magnetoresistive element whose center point is not overlapped onto a cross portion of the first and second write lines, wherein a center line of the magnetoresistive element in a direction of easy magnetization and center lines of the first and second write lines form a triangle.

### CROSS-REFERENCE TO RELATED APPLICATIONS

This application is based upon and claims the benefit of priority from prior Japanese Patent Application No. 2006-067963, filed Mar. 13, 2006, the entire contents of which are incorporated herein by reference.

### BACKGROUND OF THE INVENTION

1. Field of the Invention

The present invention relates to a magnetic random access memory (MRAM) with a magnetoresistive element as a memory cell.

2. Description of the Related Art

A magnetic random access memory has drawn attention as a next-generation new memory device, and various research and development efforts have been made toward the practical use thereof. However, as problems to be solved for that purpose, there exist many problems of making electric current low, improvement in resistance to write error, reduction in chip size, and the like.

In a conventional magnetic random access memory, some proposals have been made in terms of a shape of a magnetoresistive element, a write system, and the like in order to solve these problems.

For example, in terms of a shape of a magnetoresistive element, shapes such as a cross, a bean, a trapezoid, a bulge-plus-square, and a dent-plus-square have been proposed. Further, in terms of a write system, systems of toggle, spin-injection, and the like have been proposed (for example, refer to U.S. Pat. No. 6,545,906 and U.S. Pat. No. 6,256,223).

However, with respect to a shape of a magnetoresistive element, it is possible to obtain a given effect on making electric current low, but it is difficult to obtain sufficient resistance to write error by that effect alone. Further, if the shape is made complex, it is difficult to process it, so that it is difficult to miniaturize a memory cell and the manufacturing yield deteriorates.

In addition, with respect to the toggle system among the write systems, there is the problem that, although a given effect can be obtained on resistance to write error, it is difficult to make electric current low. Moreover, with respect to the spin-injection system, the problems of reduction in chip size, demolition of elements, or the like cannot be sufficiently handled because it is difficult to reduce a current density of a spin-injection current (write current).

### BRIEF SUMMARY OF THE INVENTION

A magnetic random access memory according to an aspect of the present invention comprises first and second write lines which cross each other, and a magnetoresistive element whose center point is not overlapped onto a cross portion of the first and second write lines, wherein a center line of the magnetoresistive element in a direction of easy magnetization and center lines of the first and second write lines form a triangle.

A magnetic random access memory according to an aspect of the present invention comprises first and second write lines which cross each other, and a magnetoresistive element which is not overlapped onto a center point of a cross portion of the first and second write lines, wherein a center line of the magnetoresistive element in a direction of easy magnetization and center lines of the first and second write lines form a triangle.

A method for writing data according to an aspect of the present invention comprises establishing a state in which a first write current flows in the first write line and a second write current flows in the second write line, writing first data into the magnetoresistive element by cutting off the second write current after the first write current is cut off, and writing second data different from the first data into the magnetoresistive element by cutting off the first write current after the second write current is cut off, on the magnetic random access memory according to claim 1.

### BRIEF DESCRIPTION OF THE SEVERAL VIEWS OF THE DRAWING

FIG. 1 is a plan view showing a cell array section according to a structural example 1;

FIG. 2 is a cross-sectional view taken along line II-II of FIG. 1;

FIG. 3 is a plan view showing a cell array section according to a structural example 2;

FIG. 4 is a cross-sectional view taken along line IV-IV of FIG. 3;

FIG. 5 is a perspective view showing a cell array section according to a structural example 3;

FIG. 6 is a cross-sectional view showing a structure of the cross-section of the cell array section of FIG. 5;

FIG. 7 is a cross-sectional view showing a structure of the cross-section of the cell array section of FIG. 5;

FIG. 8 is a diagram showing an example of a write circuit for carrying out a model of magnetization reversal 1;

FIG. 9 is a diagram showing a model of magnetization reversal 1A;

FIG. 10 is a diagram showing a model of magnetization reversal 1B;

FIG. 11 is a diagram showing a model of magnetization reversal 1C;

FIG. 12 is a diagram showing a magnetized state of a half-selected cell;

FIG. 13 is a diagram showing a magnetized state of a half-selected cell;

FIG. 14 is a diagram showing an example of a write circuit for carrying out a model of magnetization reversal 2;

FIG. 15 is a diagram showing a model of magnetization reversal 2A;

FIG. 16 is a diagram showing a model of magnetization reversal 2B;

FIG. 17 is a diagram showing a model of magnetization reversal 2C;

FIG. 18 is a diagram showing a magnetized state of a half-selected cell;

FIG. 19 is a diagram showing a magnetized state of a half-selected cell;

FIG. 20 is a diagram showing a method of writing data;

FIG. 21 is a diagram showing a modified example 1;

FIG. 22 is a diagram showing a modified example 2;

FIG. 23 is a diagram showing a modified example 3;

FIG. 24 is a diagram showing the modified example 3;

FIG. 25 is a diagram showing a modified example 4;

FIG. 26 is a diagram showing a modified example 5;

FIG. 27 is a view showing an exemplary shape of an MTJ element;

FIG. 28 is a view showing another exemplary shape of an MTJ element;

FIG. 29 is a view showing still another exemplary shape of an MTJ element;

FIG. 30 is a view showing further still another exemplary shape of an MTJ element;

FIG. 31 is a view showing an exemplary layered structure of an MTJ element;

FIG. 32 is a view showing another exemplary layered structure of an MTJ element; and

FIG. 33 is a view for determining a center line and a center point of an MTJ element.

### DETAILED DESCRIPTION OF THE INVENTION

A magnetic random access memory of an aspect of the present invention will be described below in detail with reference to the accompanying drawings.

### 1. Outline

An embodiment of the present invention is applied to a magnetic random access memory in a system of writing by using a magnetic field generated by a write current. In the embodiment of the invention, the following layouts are proposed in order to achieve improvement in resistance to write error, reduction in chip size, improvement in manufacturing yield, and the like.

One is a layout in which a center point of a magnetoresistive element is not overlapped on a cross portion of two write lines which cross each other, and a center line of the magnetoresistive element in a direction of easy magnetization and center lines of the two write lines form a triangle.

The other one is a layout in which a center point of a cross portion of two write lines which cross each other is not overlapped on a magnetoresistive element, and a center line of the magnetoresistive element in a direction of easy magnetization and center lines of the two write lines form a triangle.

Further, in the embodiment of the invention, such a layout enables to establish a state in which write currents flow in both of two write lines, and to determine a state of residual magnetization in a magnetoresistive element by shifting the timings of cutting off the write currents flowing in the two write lines.

In this case, a value of data to be written into the magnetoresistive element can be changed by merely changing the timings of cutting off the write currents flowing in the two write lines. Consequently, areas of peripheral circuits including a driver/sinker can be made smaller, and reduction in chip size can be achieved.

Further, in a state in which an electric current flows in only one of the two write lines, a magnetic domain structure in which magnetization is not easily inverted can be made, so that the resistance to write error for a half-selected cell can be improved.

Note that, since there is no limit to a shape of the magnetoresistive element in the embodiment of the invention, a simple shape such as a quadrangle, an elliptical shape, a rhombus, and a parallelogram is used, which can contribute to reduction in cell size and improvement in manufacturing yield.

Further, a shape of the magnetoresistive element is made in a shape such as a cross, a bean, a trapezoid, a bulge-plus-square, and a dent-plus-square, which can contribute to making write currents low.

### 2. Embodiments

Now, some embodiments believed to be the best will be described.

(1) Structure

A. Structural Example 1

A structural example 1 relates to a one-transistor and one-MTJ (magneto tunnel junction) type cell array structure in which a memory cell is configured by one MTJ element and one MOS transistor.

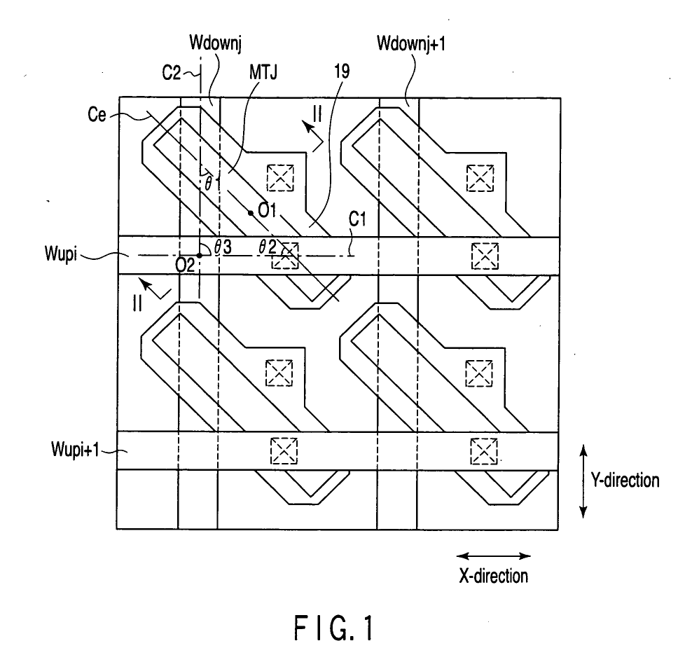

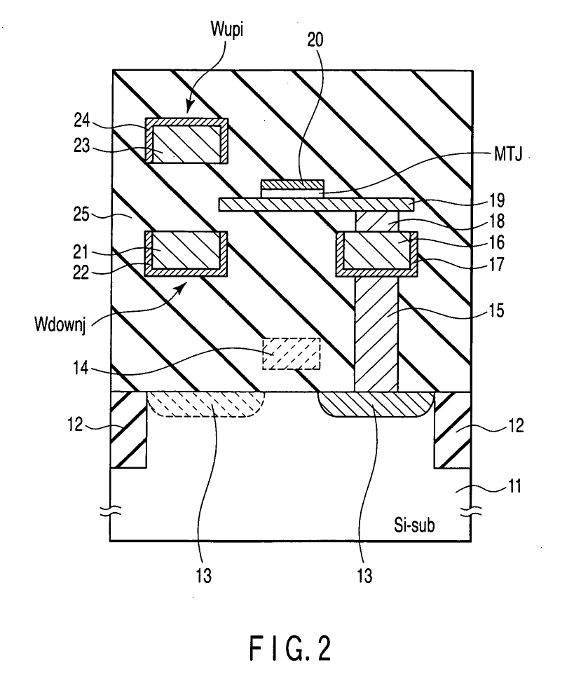

FIG. 1 shows a cell array section of a magnetic random access memory according to the structural example 1. FIG. 2 is a cross-sectional view taken along line II-II of FIG. 1.

An element isolation insulating layer 12 with a STI (shallow trench isolation) structure is formed at a surface region of a silicon substrate 11. An MOS transistor serving as a read selecting switch is formed in an elemental region surrounded by the element isolation insulating layer 12. A gate 14 of the MOS transistor elongates in the x direction as, for example, a read selecting line.

Here, the reason for that a part of the MOS transistor is shown by broken lines is the purport that a direction of the MOS transistor (direction of a channel length or a channel width) is not particularly limited, and can be set freely.

One of the source/drain diffusion layers 13 of the MOS transistor is connected to an intermediate layer 16 via a contact plug 15. Further, a yoke material (soft magnetic material) 17 is formed at the side faces and the bottom face of the intermediate layer 16.

The yoke material 17 may be not indispensable, and in place thereof, or along therewith, a barrier metal may be formed.

The intermediate layer 16 is connected to a lower electrode 19 via a contact plug 18. An MTJ element is formed on the lower electrode 19. A cap layer 20 is formed on the MTJ element.

Write lines Wupi and Wupi+1 elongate in the x direction, and are connected to one ends of the MTJ elements. The write lines Wupi and Wupi+1 also function as read lines. Further, write lines Wdownj and Wdownj+1 elongate in the y direction, and are not connected to the MTJ elements.

The write lines Wupi and Wupi+1 and the write lines Wdownj and Wdownj+1 cross each other, and at the cross portions thereof, the write lines Wupi and Wupi+1 are arranged on the write lines Wdownj and Wdownj+1.

The write lines Wdownj and Wdownj+1 each are configured by a conductive line 21 made of, for example, metal, and a yoke material 22 formed at the side faces and the bottom face of the conductive line 21.

In the same way, the write lines Wupi and Wupi+1 each are configured by a conductive line 23 made of, for example, metal, and a yoke material 24 formed at the side faces and the bottom face of the conductive line 23.

The MTJ elements have a layout so as to be arranged to be at an angle to these write lines Wupi, Wupi+1, Wdownj and Wdownj+1 at positions slightly deviating from the cross portions of the write lines Wupi and Wupi+1 and the write lines Wdownj and Wdownj+1.

Specifically, a center point O1 of the MTJ element is not overlapped onto the cross portion of the two write lines Wupi and Wdownj. Further, it can be said that a center point O2 of the cross portion of the two write lines Wupi and Wdownj is not overlapped onto the MTJ element.

Moreover, a center line Ce of the MTJ element in a direction of easy magnetization and center lines C1 and C2 of the two write lines Wupi and Wdownj form a triangle.

An insulating layer 25 covers the cell array section described above.

With such a structure, effects such as improvement in resistance to write error, reduction in chip size, improvement in manufacturing yield, and the like can be obtained by using models of magnetization reversal or a writing method which will be described later.

B. Structural Example 2

A structural example 2 relates to a cross-point type cell array structure in which a memory cell is configured by only one MTJ element.

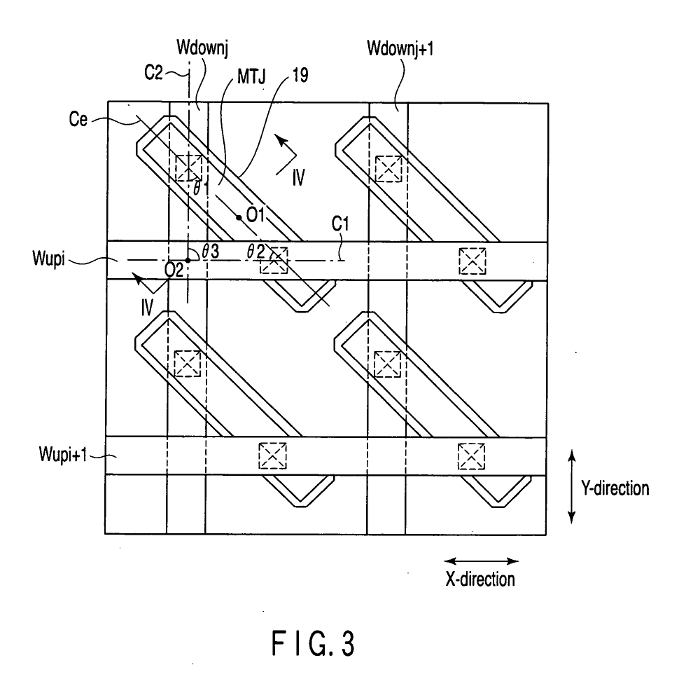

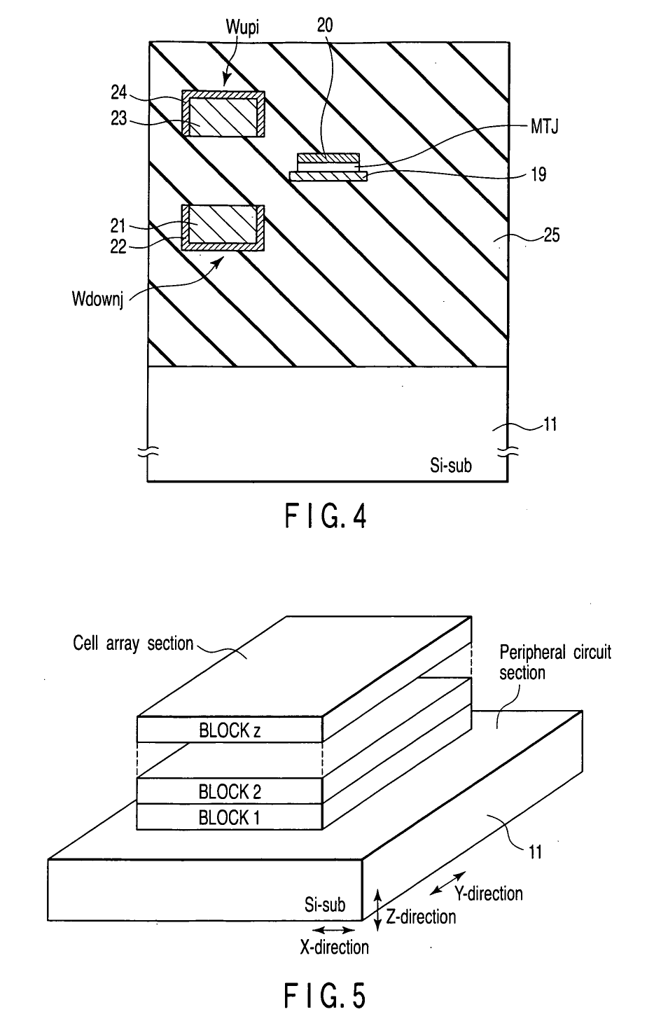

FIG. 3 shows a cell array section of a magnetic random access memory according to the structural example 2. FIG. 4 is a cross-sectional view taken along line IV-IV of FIG. 3.

An MTJ element is formed above a silicon substrate 11. The MTJ element is formed on a lower electrode 19. A cap layer 20 is formed on the MTJ element.

Nothing is formed on a surface region of the silicon substrate 11. However, an MOS transistor serving as a peripheral circuit may be formed on the surface region.

Write lines Wupi and Wupi+1 elongate in the x direction, and are connected to one ends of the MTJ elements. Write lines Wdownj and Wdownj+1 elongate in the y direction, and are connected to the other ends of the MTJ elements. The write lines Wupi and Wupi+1 and the write lines Wdownj and Wdownj+1 function as read lines as well.

Note that a rectifying device is preferably arranged between the write lines Wupi and Wupi+1 each and the MTJ element, or between the write lines Wdownj and Wdownj+1 each and the MTJ element.

For example, a contact plug between the write lines Wdownj and Wdownj+1 each and the MTJ element is made to be a laminated structure including pn junction or Schottky junction. As a consequence, a so-called sneak current that flows in an unselected MTJ element can be prevented at the time of read, and an increase in a read signal amount can be achieved.

The write lines Wupi and Wupi+1 and the write lines Wdownj and Wdownj+1 cross each other, and at the cross portions thereof, the write lines Wupi and Wupi+1 are arranged on the write lines Wdownj and Wdownj+1.

The write lines Wdownj and Wdownj+1 each are configured by a conductive line 21 made of, for example, metal, and a yoke material 22 formed at the side faces and the bottom face of the conductive line 21.

In the same way, the write lines Wupi and Wupi+1 each are configured by a conductive line 23 made of, for example, metal, and a yoke material 24 formed at the side faces and the bottom face of the conductive line 23.

The MTJ elements have a layout so as to be arranged to be at an angle to these write lines Wupi, Wupi+1, Wdownj and Wdownj+1 at positions slightly deviating from the cross portions of the write lines Wupi and Wupi+1 and the write lines Wdownj and Wdownj+1.

Specifically, in the same way as the structural example 1, a center point O1 of the MTJ element is not overlapped onto the cross portion of the two write lines Wupi and Wdownj. Further, it can be said that a center point O2 of the cross portion of the two write lines Wupi and Wdownj is not overlapped on the MTJ element.

Moreover, a center line Ce of the MTJ element in a direction of easy magnetization and center lines C1 and C2 of the two write lines Wupi and Wdownj form a triangle.

An insulating layer 25 covers the cell array section described above.

With such a structure as well, in the same way as the structural example 1, effects such as improvement in resistance to write error, reduction in chip size, improvement in manufacturing yield, and the like can be obtained by using models of magnetization reversal or a writing method which will be described later.

C. Structural Example 3

A structural example 3 is a modified example of the structural examples 1 and 2, and relates to a three-dimensional structure in which a plurality of cell array sections are stacked on a silicon substrate.

FIG. 5 shows an outline of a cell array section of a magnetic random access memory according to the structural example 3.

A plurality of blocks BLOCK1, BLOCK2, . . . BLOCKz are stacked on the silicon substrate 11. Each of the plurality of blocks BLOCK1, BLOCK2, . . . BLOCKz has a plurality of MTJ elements arranged in an array form in the x direction and y direction.

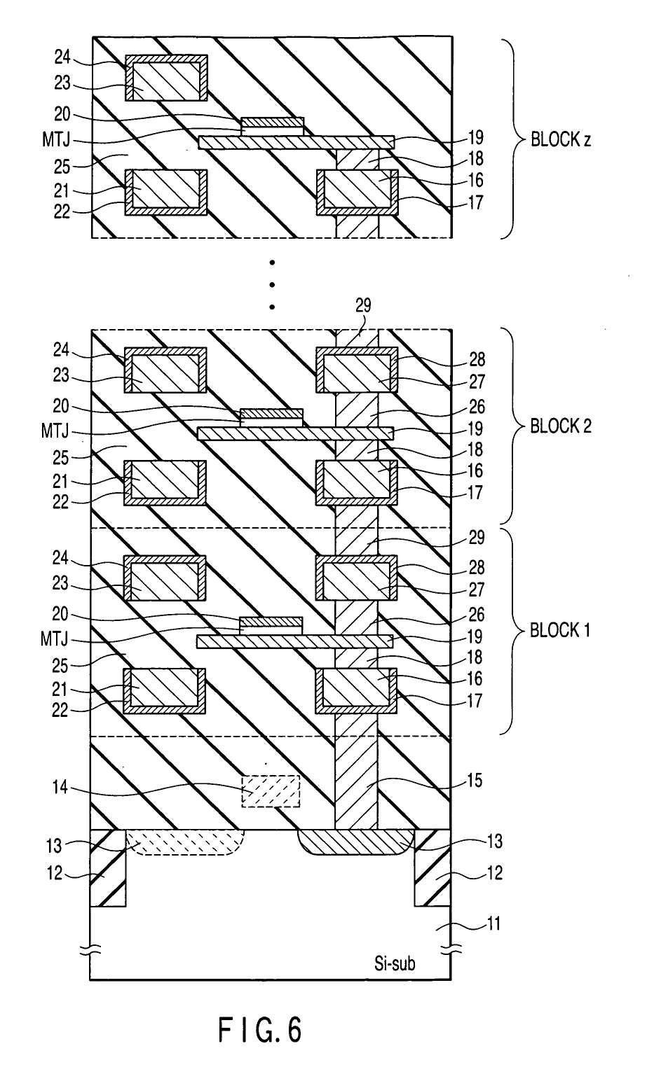

FIG. 6 shows a structure of the cross-section of the cell array section of FIG. 5, and corresponds to a modified example of the structural example 1.

In this cell array structure, z MTJ elements are connected to one MOS transistor.

The z−1 blocks BLOCK1, BLOCK2, . . . BLOCKz−1 except for the BLOCKz at the uppermost stage respectively have a same structure. The structure is the same as that of the structural example 1 of FIG. 2 except that contact plugs 26 and 29 and intermediate layers 27 and 28 are newly provided. Further, the BLOCKz at the uppermost stage is the same as that of the structural example 1 of FIG. 2.

Because the other structures, in particular, the layouts of the MTJ elements are the same as those of the structural example 1, description thereof will be omitted here.

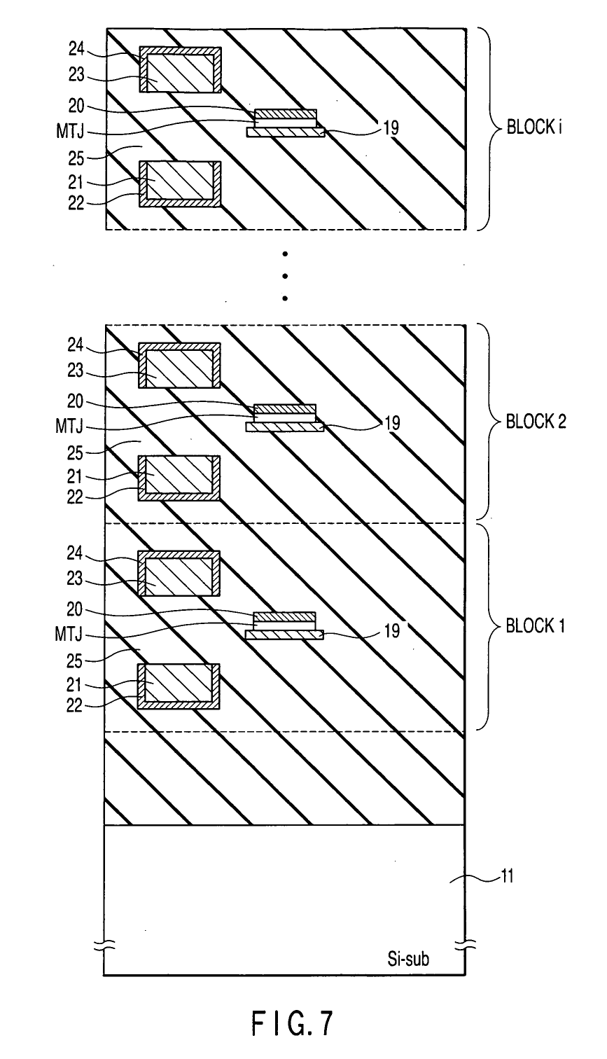

FIG. 7 shows a structure of the cross-section of the cell array section of FIG. 5, and corresponds to a modified example of the structural example 2.

In the cell array structure, cross-point type cell arrays are stacked on the silicon substrate 11.

The blocks BLOCK1, BLOCK2, . . . BLOCKz respectively have a same structure. This structure is the same as that of the structural example 2 of FIG. 4. Because the layout of the MTJ elements is also the same as that of the structural example 2, description thereof will be omitted here.

In this way, provided that the cell array section is made to be a three-dimensional structure, the bit cost can be kept low by increasing the memory capacity.

(2) Model of Magnetization Reversal 1

A model of magnetization reversal 1 relates to a model of magnetization reversal utilizing the first quadrant of an astroid curve.

A. Circuit

First, a write circuit for use in the model of magnetization reversal 1 will be described. Note that, for ease of explanation, description of a read circuit will be omitted.

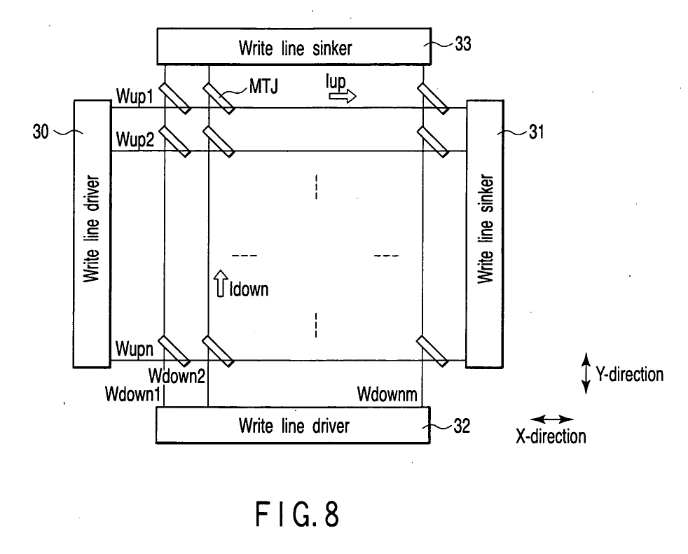

FIG. 8 shows an exemplary write circuit.

Write lines Wup1, Wup2, . . . Wupn elongate in the x direction. A write line driver 30 is connected to one ends of the write lines Wup1, Wup2, . . . Wupn, and a write line sinker 31 is connected to the other ends thereof.

In addition, write lines Wdown1, Wdown2, . . . Wdownm elongate in the y direction. A write line driver 32 is connected to one ends of the write lines Wdown1, Wdown2, . . . Wdownm, and a write line sinker 33 is connected to the other ends thereof.

MTJ elements are arranged in an array form at positions slightly deviating from the cross portions of the write lines Wup1, Wup2, . . . Wupn, and the write lines Wdown1, Wdown2, . . . Wdownm.

The write circuit is featured in that, in the same way as in the case of using the toggle write system, it suffices to make only write currents Iup and Idown heading in one direction flow in the write lines Wup1, Wup2, . . . Wupn and the write lines Wdown1, Wdown2, Wdownm.

Namely, because there is no need to connect drivers/sinkers respectively to the both ends of the write lines Wup1, Wup2, . . . Wupn or the write lines Wdown1, Wdown2, . . . Wdownm, the area of the write circuit can be made smaller, which can contribute to reduction in chip area.

Furthermore, in accordance with models of magnetization reversal or a writing method described later, there is no need to carry out a read operation before a write operation as in the toggle write system, and thus, speeding up of a write operation can be achieved.

B. Description of Model of Magnetization Reversal 1

A model of magnetization reversal 1 according to the embodiment of the present invention is featured in that an area or a volume of a free layer of an MTJ element whose magnetization can be controlled by a write current flowing in one of two write lines is made smaller than ½ of an area or a volume of the entire free layer of the MTJ element.

In this case, with respect to a selected MTJ element (selected cell) arranged at a position slightly deviating from the cross portion of the two write lines in which write currents flow, it is possible to control the magnetization of half or more of an area or a volume of the free layer by the write currents flowing in the two write lines, whereby magnetization reversal is possible.

In contrast thereto, with respect to a half-selected MTJ element (half-selected cell) which receives a magnetic field due to a write current from one of the two write lines, only the magnetization at a region less than ½ of an area or a volume of the free layer can be controlled, and thus, magnetization reversal is impossible.

Hereinafter, concrete examples will be described.

Model of Magnetization Reversal 1A

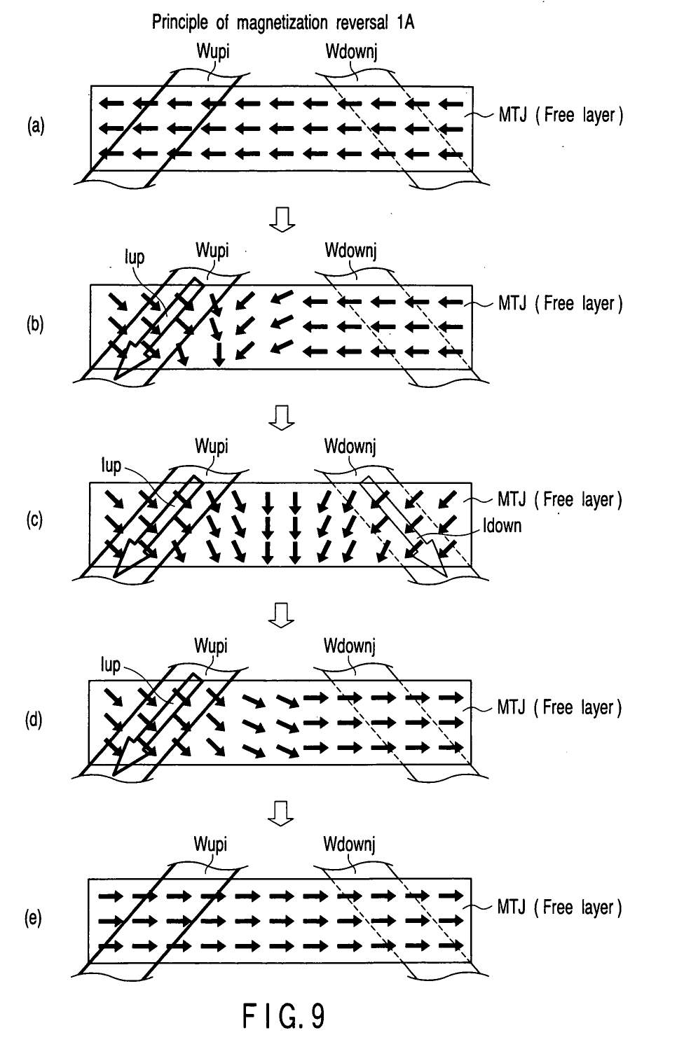

In an initial state, the magnetization of the free layer of the MTJ element is directed toward the left as shown in (a) of FIG. 9.

First, as shown in (b) of FIG. 9, a part of the magnetized state of the free layer of the MTJ element is changed by making the write current Iup flow in the upper write line Wupi. Thereafter, as shown in (c) of FIG. 9, more than half of an area or a volume of the free layer of the MTJ element is changed by making the write current Idown flow in the lower write line Wdownj.

Subsequently, as shown in (d) of FIG. 9, most of the magnetization of the free layer of the MTJ element is directed toward the right when the write current Idown flowing in the lower write line Wdownj is cut off. Then, as shown in (e) of FIG. 9, the magnetization of the free layer of the MTJ element is directed toward the right when the write current Iup flowing in the upper write line Wupi is cut off.

Model of Magnetization Reversal 1B

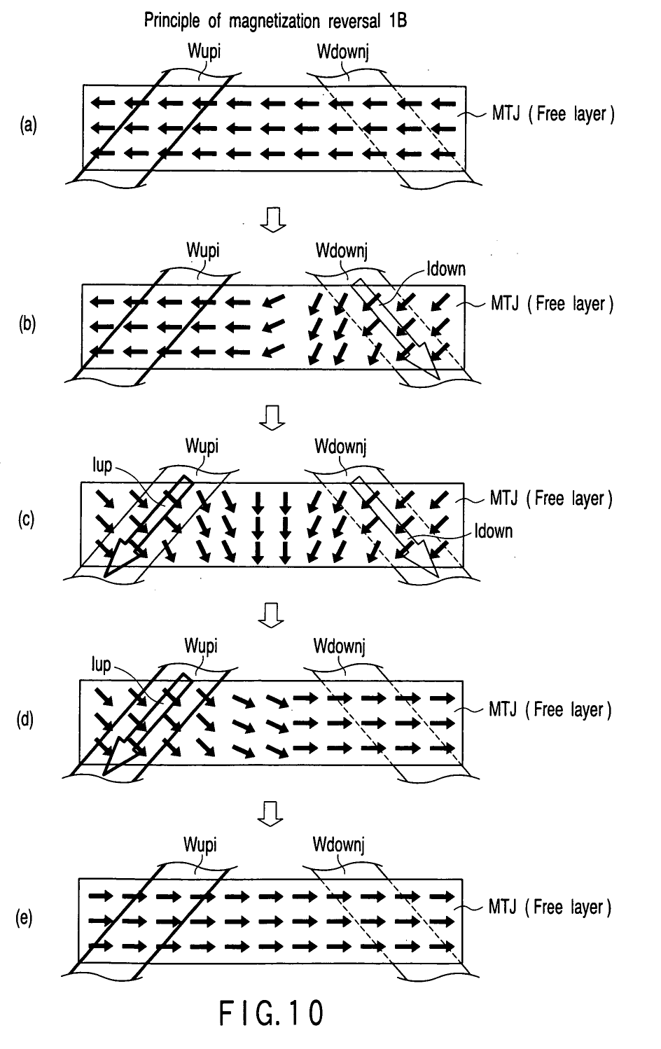

In an initial state, the magnetization of the free layer of the MTJ element is directed toward the left as shown in (a) of FIG. 10.

First, as shown in (b) of FIG. 10, a part of the magnetized state of the free layer of the MTJ element is changed by making the write current Idown flow in the lower write line Wdownj. Thereafter, as shown in (c) of FIG. 10, more than half of an area or a volume of the free layer of the MTJ element is changed by making the write current Iup flow in the upper write line Wupi.

Subsequently, as shown in (d) of FIG. 10, most of the magnetization of the free layer of the MTJ element is directed toward the right when the write current Idown flowing in the lower write line Wdownj is cut off. Then, as shown in (e) of FIG. 10, the magnetization of the free layer of the MTJ element is directed toward the right when the write current Iup flowing in the upper write line Wupi is cut off.

Model of Magnetization Reversal 1C

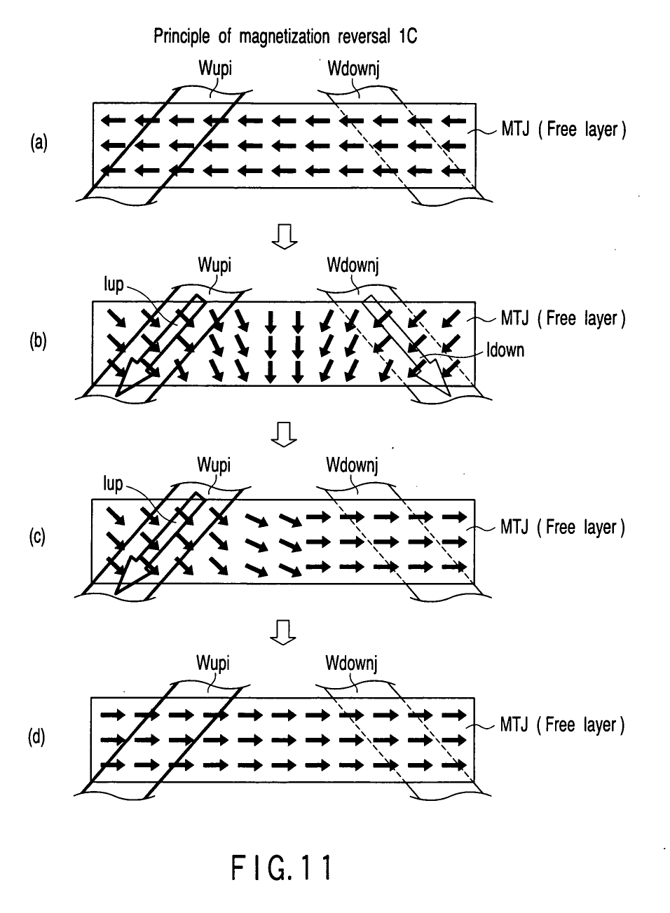

In an initial state, the magnetization of the free layer of the MTJ element is directed toward the left as shown in (a) of FIG. 11.

First, as shown in (b) of FIG. 11, the write current Iup is made to flow in the upper write line Wupi, and at the same time, the write current Idown is made to flow in the lower write line Wdownj, whereby the magnetized state of half or more of an area or a volume of the free layer of the MTJ element is changed.

Thereafter, as shown in (c) of FIG. 11, most of the magnetization of the free layer of the MTJ element is directed toward the right when the write current Idown flowing in the lower write line Wdownj is cut off. Then, as shown in (d) of FIG. 11, the magnetization of the free layer of the MTJ element is directed toward the right when the write current Iup flowing in the upper write line Wupi is cut off.

Magnetized State of Half-Selected Cell

In the models of magnetization reversal 1A, 1B and 1C, the write current Iup is made to flow in the upper write line Wupi, the write current Idown is made to flow in the lower write line Wdownj, and timings of cutting off the both currents are shifted to thereby achieve the magnetization reversal.

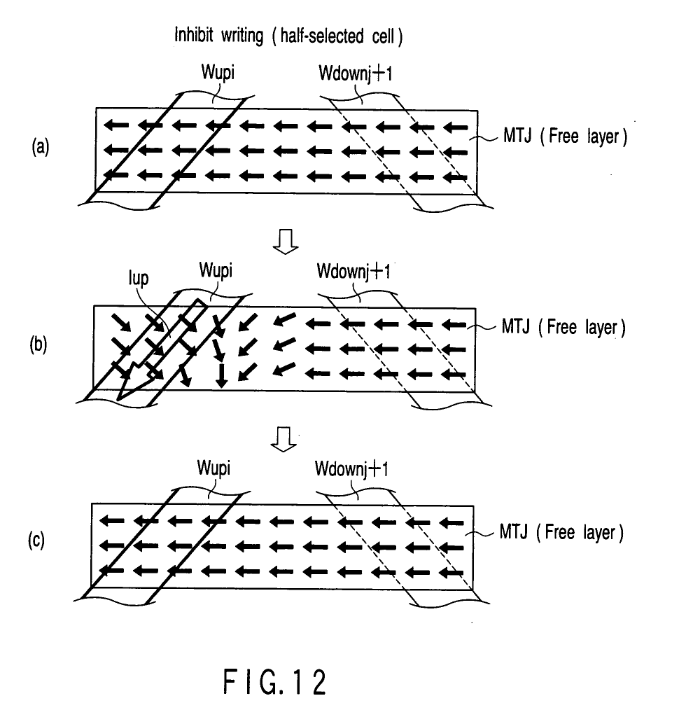

Here, as shown in, for example, (a) to (c) of FIG. 12, in an MTJ element (half-selected cell) to which only a magnetic field due to the write current Iup flowing in the upper write line Wupi is applied, magnetization reversal is not achieved since only the magnetization in a region less than ½ of an area or a volume of the entire free layer is changed.

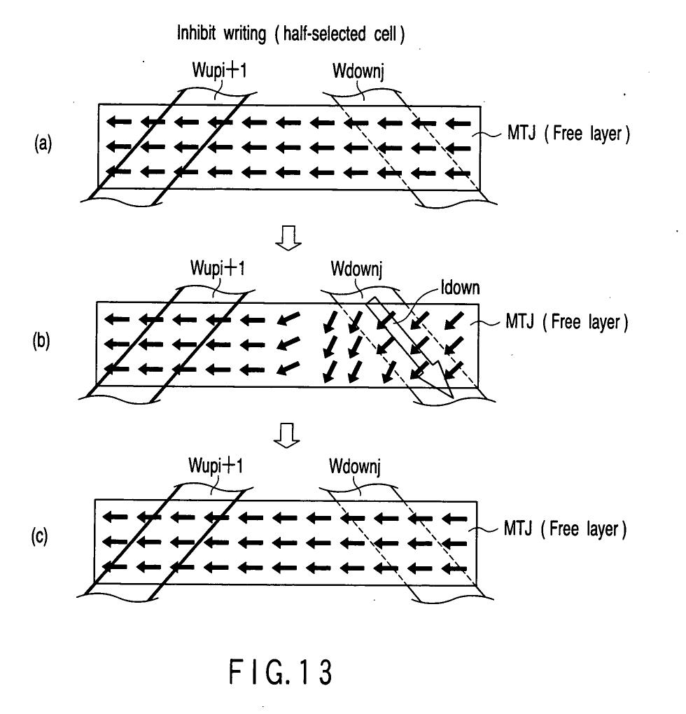

In the same way, as shown in, for example, (a) to (c) of FIG. 13, also in an MTJ element (half-selected cell) to which only a magnetic field due to the write current Idown flowing in the lower write line Wdownj is applied, magnetization reversal is not achieved since only the magnetization in a region less than ½ of an area or a volume of the entire free layer is changed.

In this way, write error can be effectively prevented for a half-selected cell.

This effect can be obtained even when values of the write currents Iup and Idown are made to be extremely great values by adjusting, for example, an element size, a switched connection constant of the free layer, or the like. Consequently, a magnetic random access memory having a great write margin can be provided.

(3) Model of Magnetization Reversal 2

A model of magnetization reversal 2 relates to a model of magnetization reversal utilizing the third quadrant of an astroid curve.

A. Circuit

First, a write circuit for use in the model of magnetization reversal 2 will be described. Note that, for ease of explanation, description of a read circuit will be omitted.

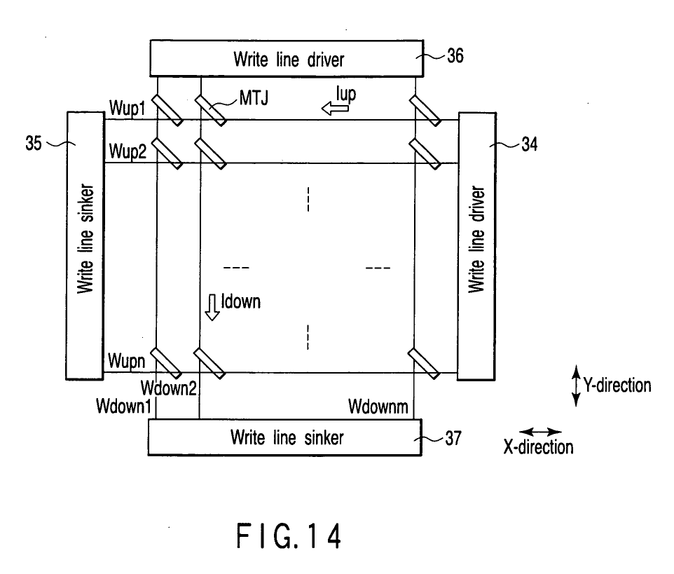

FIG. 14 shows an exemplary write circuit.

The write lines Wup1, Wup2, . . . Wupn elongate in the x direction. A write line driver 34 is connected to one ends of the write lines Wup1, Wup2, . . . Wupn, and a write line sinker 35 is connected to the other ends thereof.

Further, the write lines Wdown1, Wdown2, . . . Wdownm elongate in the y direction. A write line driver 36 is connected to one ends of the write lines Wdown1, Wdown2, . . . Wdownm, and a write line sinker 37 is connected to the other ends thereof.

MTJ elements are arranged in an array form at positions slightly deviating from the cross portions of the write lines Wup1, Wup2, . . . Wupn, and the write lines Wdown1, Wdown2, . . . Wdownm.

In this write circuit, only the write currents Iup and Idown heading in one direction flow in the write lines Wup1, Wup2, . . . Wupn, and the write lines Wdown1, Wdown2, . . . Wdownm, as described in the model of magnetization reversal 1.

However, since the third quadrant of an astroid curve is used in the model of magnetization reversal 2, the directions of the write currents Iup and Idown are opposite to those in the model of magnetization reversal 1.

With such a structure as well, there is no need to connect drivers/sinkers respectively to the both ends of the write lines Wup1, Wup2, . . . Wupn, and the write lines Wdown1, Wdown2, . . . Wdownm, the area of the write circuit can be made smaller, which can contribute to reduction in chip area.

In addition, there is no need to carry out a read operation before a write operation as in the toggle write system, and thus, speeding up of a write operation can be achieved.

B. Description of Model of Magnetization Reversal 2

The model of magnetization reversal 2 is completely the same as the model of magnetization reversal 1 except that the quadrant of an astroid curve to be used is different.

The model of magnetization reversal 2 according to the embodiment of the invention is featured in that an area or a volume of a free layer of an MTJ element whose magnetization can be controlled by a write current flowing in one of two write lines is made smaller than ½ of an area or a volume of the entire free layer of the MTJ element.

In this case, with respect to a selected MTJ element (selected cell) arranged at a position slightly deviating from the cross portion of the two write lines in which write currents flow, it is possible to control the magnetization of half or more of an area or a volume of the free layer by the write currents flowing in the two write lines, and thus, magnetization reversal is possible.

In contrast thereto, with respect to a half-selected MTJ element (half-selected cell) which receives a magnetic field due to a write current from one of two write lines, magnetization reversal is impossible because only the magnetization in a region less than ½ of an area or a volume of the free layer can be controlled.

Hereinafter, concrete examples will be described.

Model of Magnetization Reversal 2A

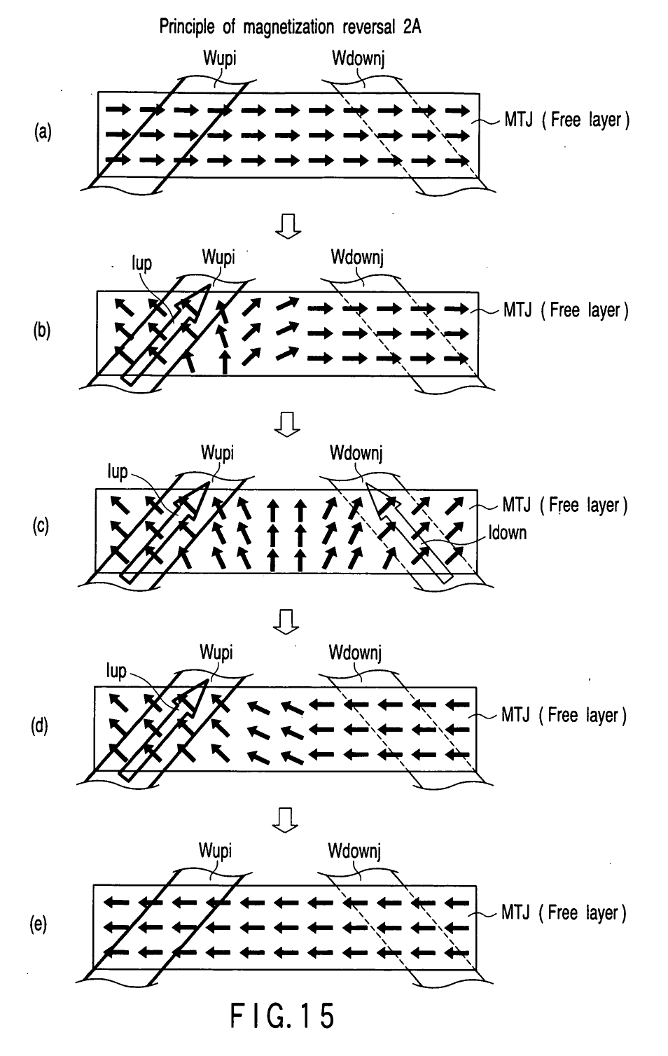

In an initial state, the magnetization of the free layer of the MTJ element is directed toward the right as shown in (a) of FIG. 15.

First, as shown in (b) of FIG. 15, a part of the magnetized state of the free layer of the MTJ element is changed by making the write current Iup flow in the upper write line Wupi. Thereafter, as shown in (c) of FIG. 15, the magnetized state of half or more of an area or a volume of the free layer of the MTJ element is changed by making the write current Idown flow in the lower write line Wdownj.

Subsequently, as shown in (d) of FIG. 15, most of the magnetization of the free layer of the MTJ element is directed toward the left when the write current Idown flowing in the lower write line Wdownj is cut off. Then, as shown in (e) of FIG. 15, the magnetization of the free layer of the MTJ element is directed toward the left when the write current Iup flowing in the upper write line Wupi is cut off.

Model of Magnetization Reversal 2B

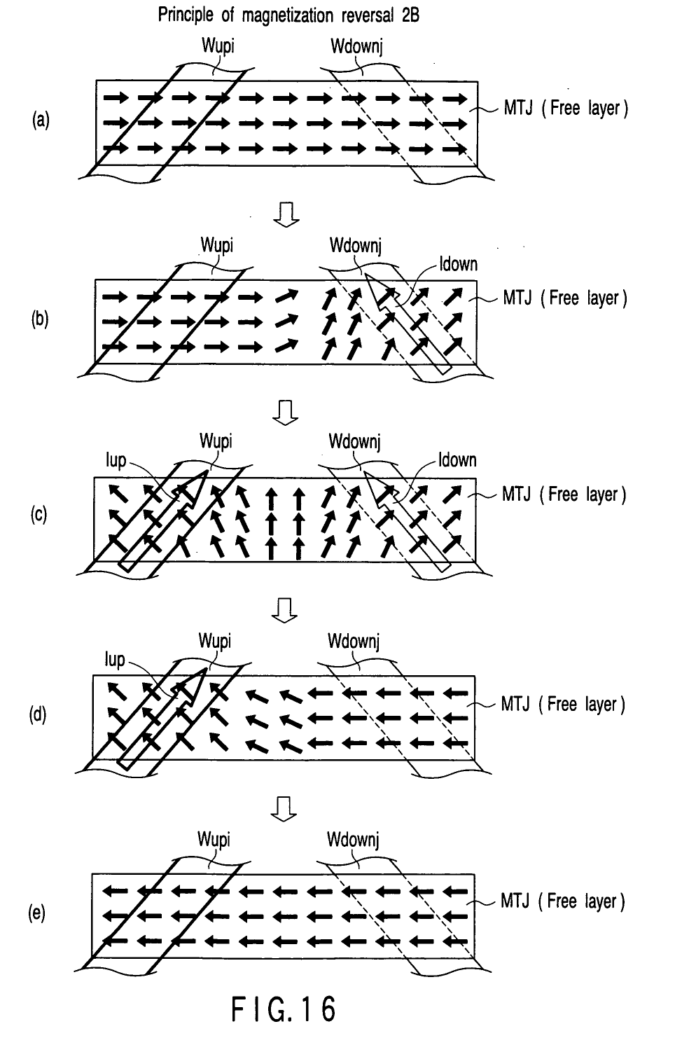

In an initial state, the magnetization of the free layer of the MTJ element is directed toward the right as shown in (a) of FIG. 16.

First, as shown in (b) of FIG. 16, a part of the magnetized state of the free layer of the MTJ element is changed by making the write current Idown in the lower write line Wdownj. Thereafter, as shown in (c) of FIG. 16, the magnetized state of half or more of an area or a volume of the free layer of the MTJ element is changed by making the write current Iup flow in the upper write line Wupi.

Subsequently, as shown in (d) of FIG. 16, most of the magnetization of the free layer of the MTJ element is directed toward the left when the write current Idown flowing in the lower write line Wdownj is cut off. Then, as shown in (e) of FIG. 16, the magnetization of the free layer of the MTJ element is directed toward the left when the write current Iup flowing in the upper write line Wupi is cut off.

Model of Magnetization Reversal 2C

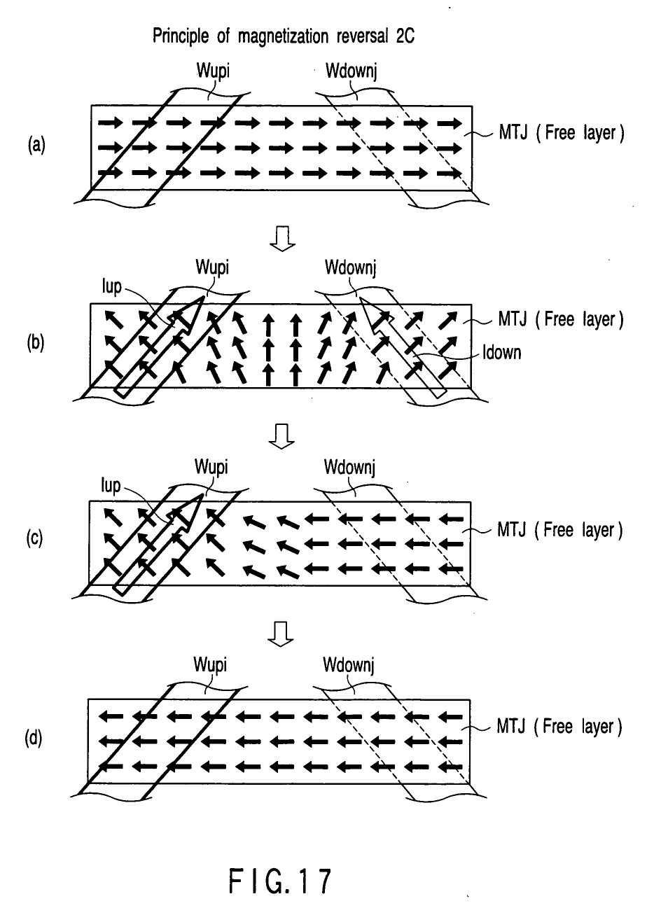

In an initial state, the magnetization of the free layer of the MTJ element is directed toward the right as shown in (a) of FIG. 17.

First, as shown in (b) of FIG. 17, the write current Iup is made to flow in the upper write line Wupi, and at the same time, the write current Idown is made to flow in the lower write line Wdownj, whereby the magnetized state of half or more of an area or a volume of the free layer of the MTJ element is changed.

Thereafter, as shown in (c) of FIG. 17, most of the magnetization of the free layer of the MTJ element is directed toward the left when the write current Idown flowing in the lower write line Wdownj is cut off. Then, as shown in (d) of FIG. 17, the magnetization of the free layer of the MTJ element is directed toward the left when the write current Iup flowing in the upper write line Wupi is cut off.

Magnetized State of Half-Selected Cell

In the models of magnetization reversal 2A, 2B and 2C, the write current Iup is made to flow in the upper write line Wupi, the write current Idown is made to flow in the lower write line Wdownj, and timings of cutting off the both currents are shifted to thereby achieve the magnetization reversal.

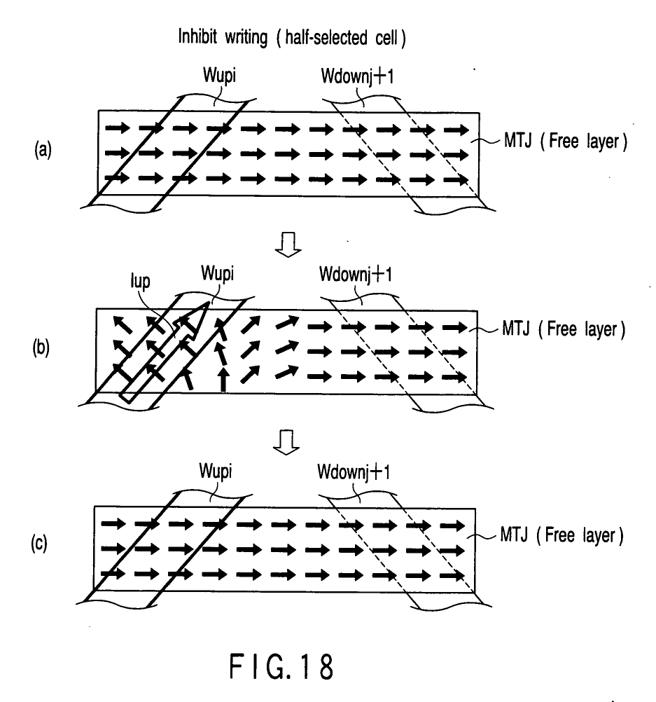

Here, as shown in, for example, (a) to (c) of FIG. 18, in an MTJ element (half-selected cell) to which only a magnetic field due to the write current Iup flowing in the upper write line Wupi is applied, magnetization reversal is not achieved because only the magnetization in a region less than ½ of an area or a volume of the entire free layer is changed.

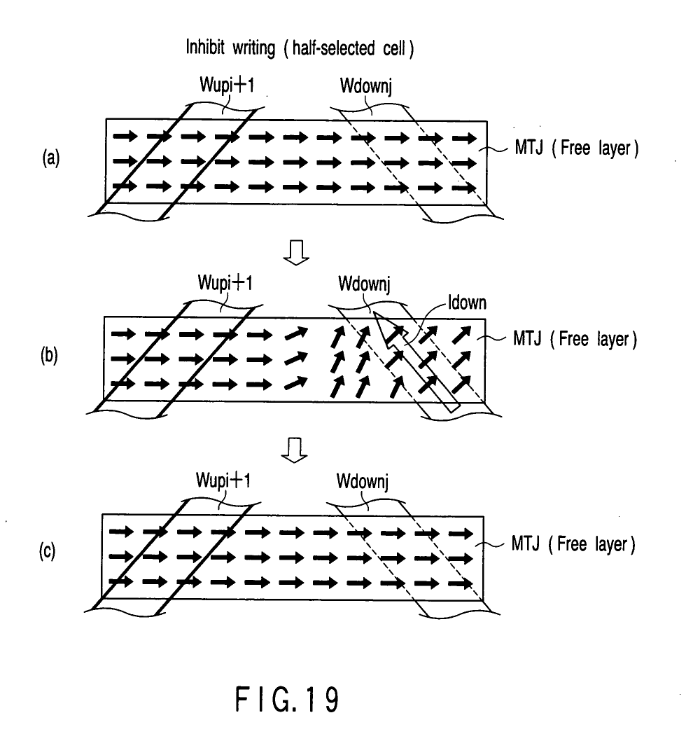

In the same way, as shown in, for example, (a) to (c) of FIG. 19, also in an MTJ element (half-selected cell) to which only a magnetic field due to the write current Idown flowing in the lower write line Wdownj is applied, magnetization reversal is not achieved because only the magnetization in a region less than ½ of an area or a volume of the entire free layer is changed.

In this way, write error can be effectively prevented for a half-selected cell.

This effect can be obtained even when values of the write currents Iup and Idown are made to be extremely great values by adjusting, for example, an element size, a switched connection constant of the free layer, or the like. Consequently, a magnetic random access memory having a great write margin can be provided.

(4) Writing Method

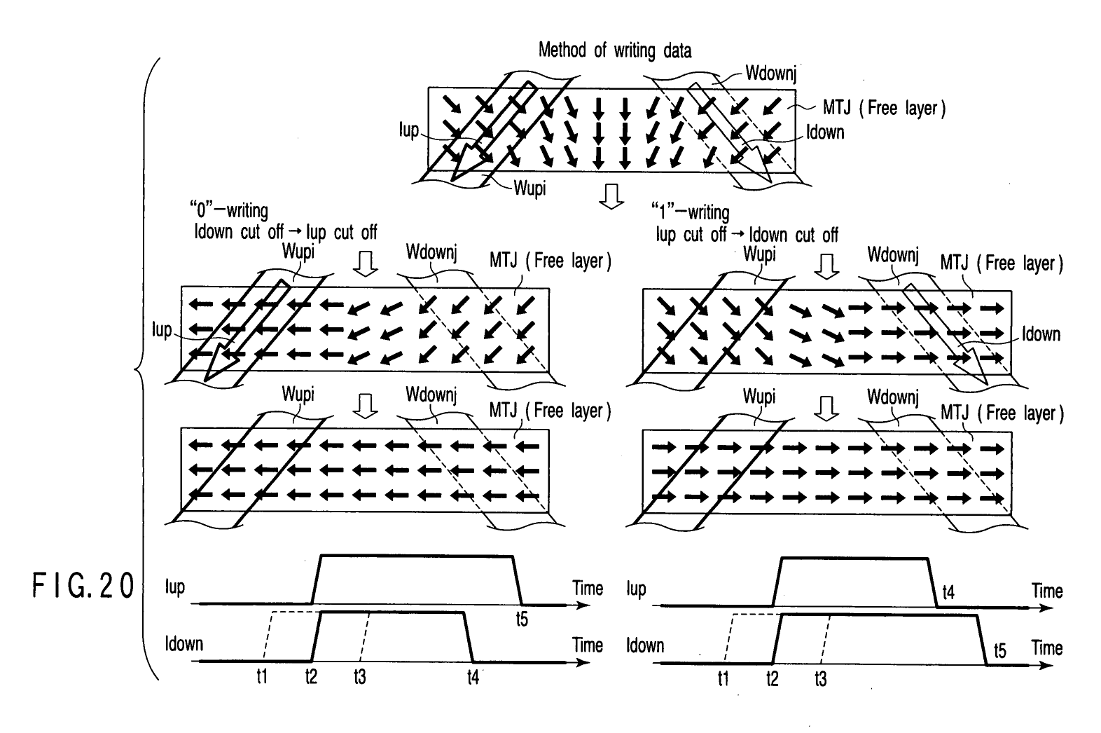

FIG. 20 shows a writing method according to the embodiment of the present invention.

The writing method according to the embodiment of the invention is featured in that “0”-writing and “1”-writing are achieved in such a manner as to establish a state in which write currents flow in both of two write lines, and thereafter, control timings of cutting off the write currents flowing in the two write lines.

Here, suppose that the magnetization of a pinned layer of an MTJ element is fixed so as to be directed toward the left. Then, a state in which the magnetization of the pinned layer and the magnetization of the free layer of the MTJ element are parallel to each other is defined as a “0” state (low-resistive state), and a state in which those are anti-parallel to each other is defined as a “1” state (high-resistive state).

For example, in a case of “0”-writing, the write current Iup flowing in the upper write line Wupi is cut off at a time t5 after the write current Idown flowing in the lower write line Wdownj is cut off at a time t4. Consequently, the state of the residual magnetization of the free layer of the MTJ element is directed toward the left, which can achieve “0” writing.

Further, in a case of “1” writing, the write current Idown flowing in the lower write line Wdownj is cut off at a time t5 after the write current Iup flowing in the upper write line Wupi is cut off at a time t4. Consequently, the state of the residual magnetization of the free layer of the MTJ element is directed toward the right, which can achieve “1” writing.

In this way, “0”/“1” data can be written into the MTJ elements by controlling the timings of cutting off the write currents Iup and Idown.

Note that the timings t1, t2 and t3 of making the write currents Iup and Idown flow may be in any relationship.

(5) Effects

As described above, in accordance with the embodiment of the invention, desired data can be written into the MTJ element by merely controlling timings of falls of current pulses respectively applied to the two write lines.

Moreover, a direction in which current pulse advances does not depend on a value of write data, and may be always one direction. Accordingly, a chip area can be reduced by reducing the write circuit.

Further, according to the models of magnetization reversal or the writing method according to the embodiment of the invention, there is no need to read out data of a selected cell in advance of writing as in the toggle write system, and therefore, speeding up of a write operation can be achieved.

With respect to the problem of write error for a half-selected cell, a size of an MTJ element, a switched connection constant of a free layer, and the like are adjusted, whereby it is possible for magnetization reversal not to be generated even if an extremely great electric current flows in only one of the two write lines. As a consequence, a magnetic random access memory having a great write margin can be realized.

In the embodiment of the present invention, a shape of an MTJ element is not limited. For this reason, a simple shape such as a quadrangle, an elliptical shape, a rhombus, and a parallelogram, which makes an attempt to shrink a memory cell and improve a manufacturing yield.

Further, if a shape of an MTJ element is made in a shape such as a cross, a bean, a trapezoid, a bulge-plus-square, and a dent-plus-square, making write currents low and improvement in resistance to write error can be simultaneously achieved.

### 3. Modified Examples

Because various modifications are possible with respect to the magnetic random access memory according to the embodiment of the invention, some of those will be described.

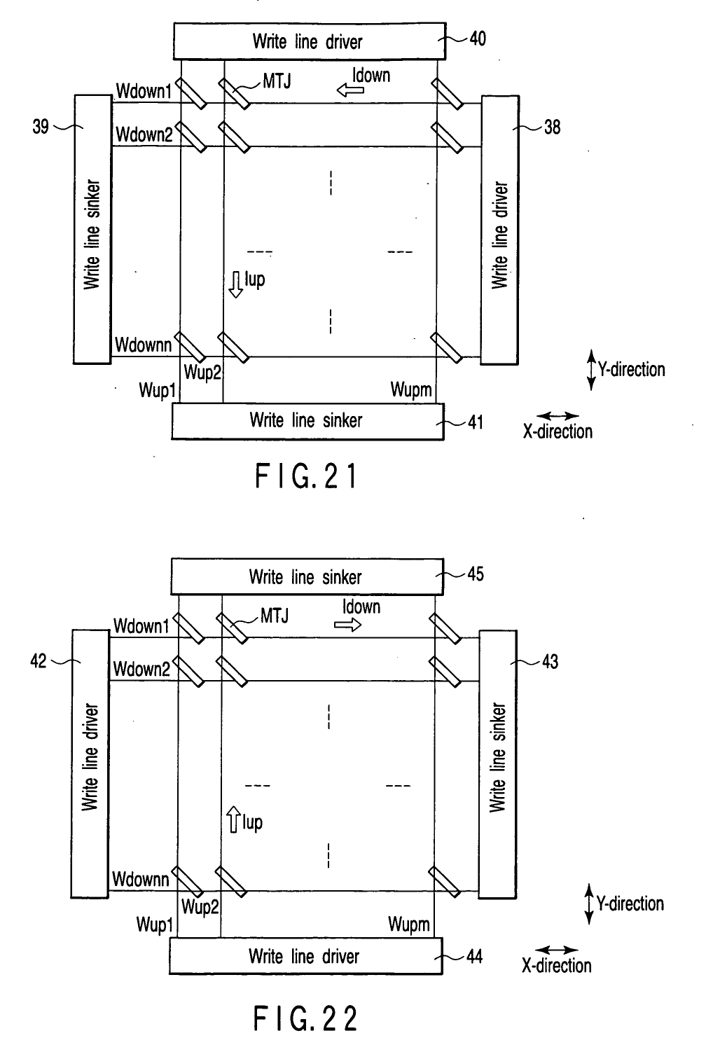

FIG. 21 shows a modified example 1.

The modified example 1 is different from, for example, the circuit of FIG. 8 in that the write lines Wdown1, Wdown2, . . . Wdownn arranged below the MTJ elements elongate in the x direction, and that the write lines Wup1, Wup2, . . . Wupm arranged above the MTJ elements elongate in the y direction.

Therefore, a write driver 38 is connected to one ends (the right ends) of the write lines Wdown1, Wdown2, . . . Wdownn, and a write sinker 39 is connected to the other ends (the left ends) of the write lines Wdown1, Wdown2, . . . Wdownn.

In addition, a write driver 40 is connected to one ends (the top ends) of the write lines Wup1, Wup2, Wupm, and a write sinker 41 is connected to the other ends (the bottom ends) of the write lines Wup1, Wup2, Wupm.

FIG. 22 shows a modified example 2.

The modified example 2 is different from, for example, the circuit of FIG. 14, in that the write lines Wdown1, Wdown2, . . . Wdownn arranged below the MTJ elements elongate in the x direction, and that the write lines Wup1, Wup2, . . . Wupm arranged above the MTJ elements elongate in the y direction.

Therefore, a write driver 42 is connected to one ends (the left ends) of the write lines Wdown1, Wdown2, . . . Wdownn, and a write sinker 43 is connected to the other ends (the right ends) of the write lines Wdown1, Wdown2, . . . Wdownn.

Further, a write driver 44 is connected to one ends (the bottom ends) of the write lines Wup1, Wup2, Wupm, and a write sinker 45 is connected to the other ends (the top ends) of the write lines Wup1, Wup2, Wupm.

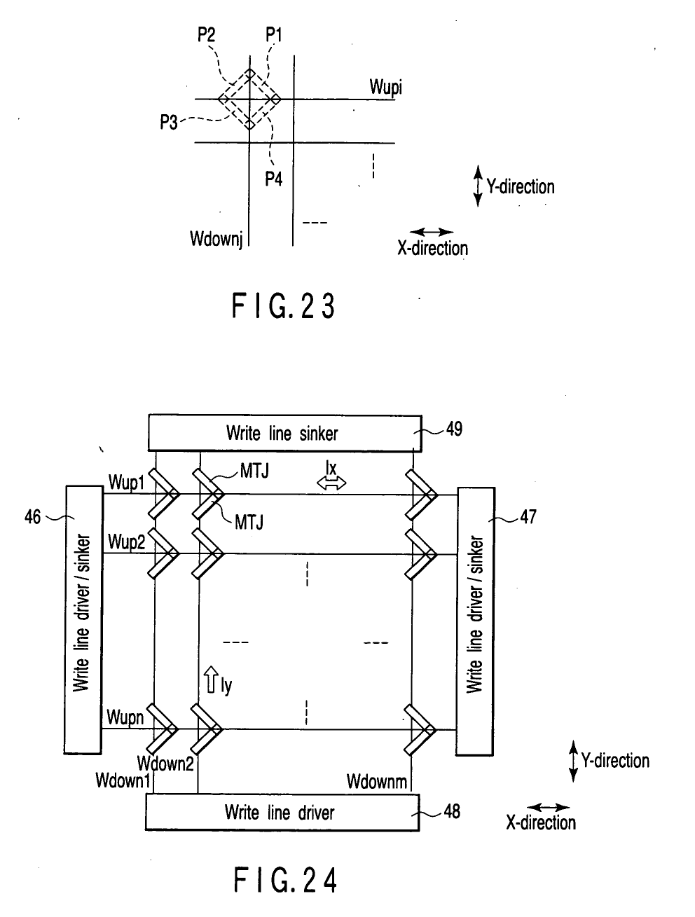

FIG. 23 shows a modified example 3.

The modified example 3 relates to a direction of an MTJ element.

In a case of carrying out writing by utilizing the first quadrant of an astroid curve, a direction of an MTJ element is set to P1. Alternatively, in a case of carrying out writing by utilizing the second, third, or fourth quadrant of an astroid curve, a direction of an MTJ element is respectively set to P1, P2, or P3.

A plurality of MTJ elements may be arranged at a cross portion of two write lines. For example, writing can be carried out by utilizing the first and fourth quadrants of an astroid curve, as shown in FIG. 24.

In this case, a write driver/sinker 46 is arranged at one ends of the write lines Wup1, Wup2, . . . Wupn, and a write driver/sinker 47 is arranged at the other ends thereof. Further, a write driver 48 is connected to one ends of the write lines Wdown1, Wdown2, . . . Wdownm, and a write sinker 49 is connected to the other ends thereof.

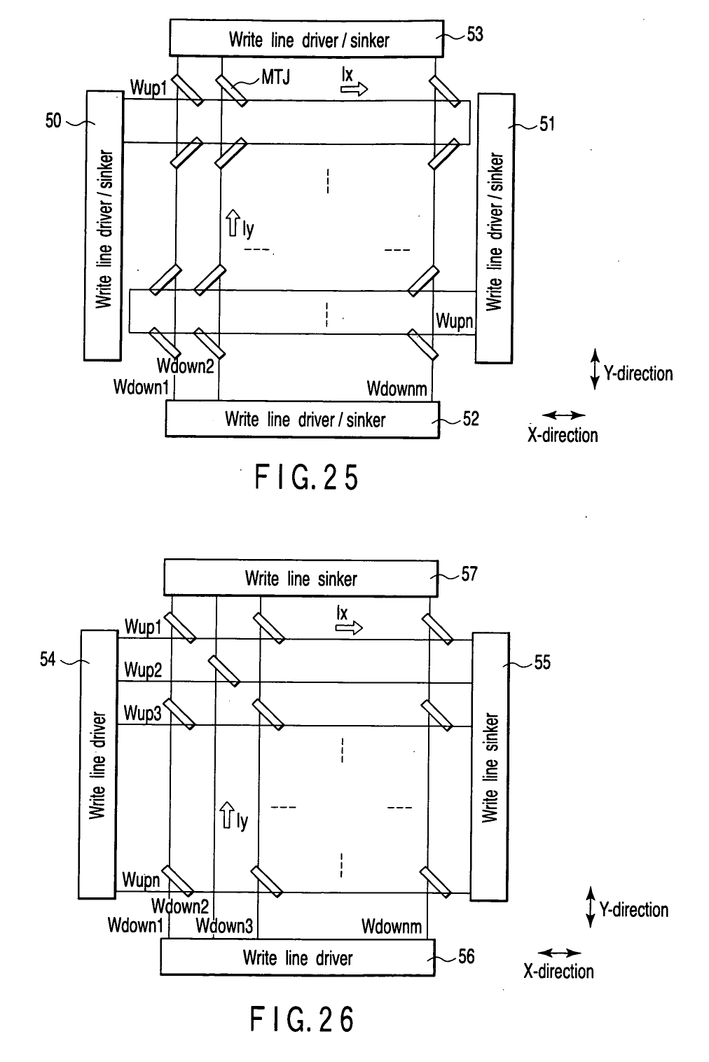

FIG. 25 shows a modified example 4.

The modified example 4 relates to a write line with a folded structure.

One of the two write lines, in this example, the write lines Wup1, . . . Wupn have a folded structure. In this case, two MTJ elements adjacent to each other in the y direction are arranged axisymmetrically because writing is carried out by utilizing the first and fourth quadrants of an astroid curve.

A write driver/sinker 50 is arranged at one ends of the write lines Wup1, Wup2, . . . Wupn, and a write driver/sinker 51 is arranged at the other ends thereof. Further, a write driver/sinker 52 is connected to one ends of the write lines Wdown1, Wdown2, . . . Wdownm, and a write driver/sinker 53 is connected to the other ends thereof.

Note that the upper-and-lower relationship between the write lines Wup1, Wup2, . . . Wupn and the write lines Wdown1, Wdown2, . . . Wdownm may be inverted.

FIG. 26 shows a modified example 5.

The modified example 5 is different from, for example, the circuit of FIG. 8, in that the MTJ elements are arranged in a houndstooth check form at positions slightly deviating from the cross portions of the write lines the write lines Wup1, Wup2, . . . Wupn, and the write lines Wdown1, Wdown2, . . . Wdownm.

A write driver 54 is connected to one ends of the write lines Wup1, Wup2, . . . Wupn, and a write sinker 55 is connected to the other ends of the write lines Wup1, Wup2, . . . Wupn.

Further, a write driver 56 is connected to one ends of the write lines Wdown1, Wdown2, . . . Wdownm, and a write sinker 57 is connected to the other ends of the write lines Wdown1, Wdown2, . . . Wdownm.

Also in the modified examples 1 to 5, the same effects as those described in the embodiment can be obtained.

### 4. MTJ Elements

In the embodiment of the invention, there is no limit particularly to a shape of an MTJ element.

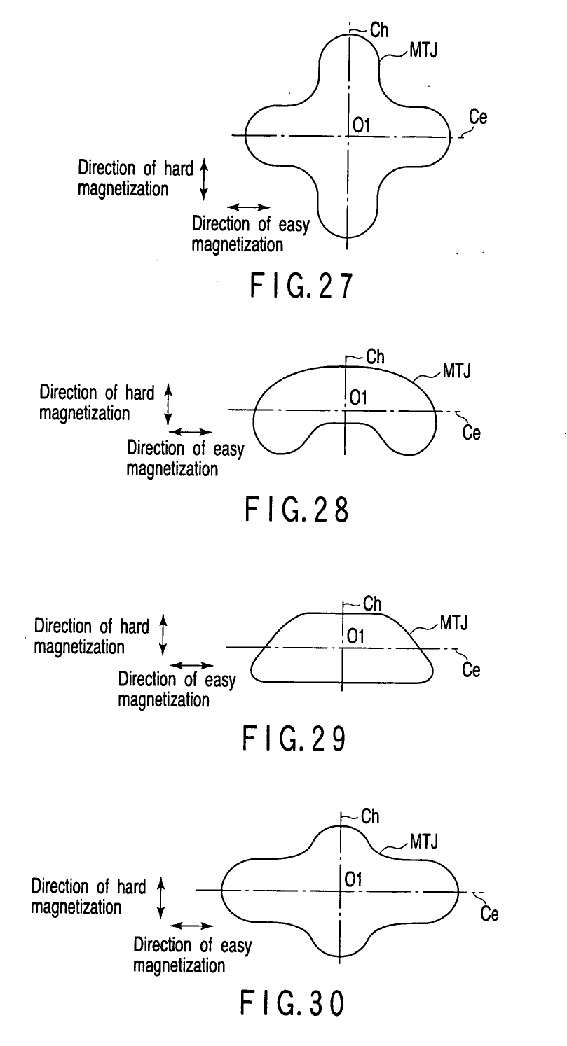

For example, the shape may be a cross as shown in FIG. 27, may be a bean as shown in FIG. 28, may be a trapezoid as shown in FIG. 29, and may be a bulge-plus-square as shown in FIG. 30.

An MTJ element is arranged, for example, such that the center point O1 is not overlapped onto the cross portion of the two write lines.

Furthermore, there is no limit particularly to the layered structure of an MTJ element.

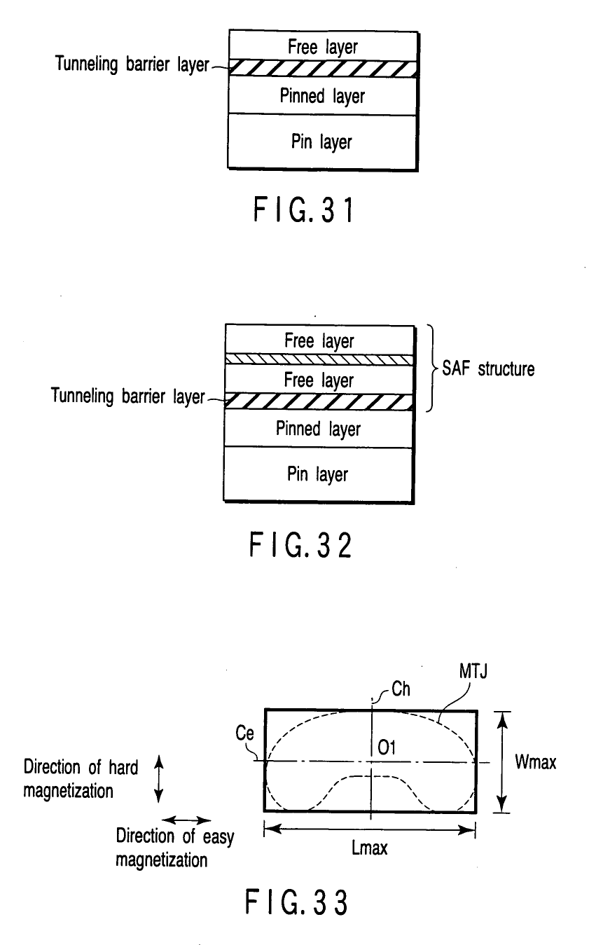

For example, an MTJ element may have a basic structure configured by a pin layer, a pinned layer, a tunneling barrier layer, and a free layer as shown in FIG. 31, and may have a synthetic anti-ferromagnetic (SAF) structure having two free layers which are anti-ferromagnetically combined (ferromagnetic layers) as shown in FIG. 32.

With respect to the magnetic anisotropy of an MTJ element, the shape magnetic anisotropy may be dominant, or the induced magnetic anisotropy may be dominant.

When a shape of an MTJ element is made complex, the center point and the center line of the MTJ element are determined as follows.

Supposing that a maximum length of the MTJ element in a direction of easy magnetization is Lmax and a maxium width of the MTJ element in a direction of hard magnetization is Wmax, a rectangle of Lmax×Wmax is made as shown in FIG. 33.

Then, the center line Ce of the MTJ element in a direction of easy magnetization is a line connecting the points dividing Wmax in half, and the center line Ch of the MTJ element in a direction of hard magnetization is a line connecting the points dividing Lmax in half. The center point O1 of the MTJ element is a cross-point of the center lines Ce and Ch.

### 5. Others

The embodiment of the invention enables to achieve improvement in resistance to write error, reduction in chip size, improvement in manufacturing yield, and the like of a magnetic random access memory.

With respect to the two write lines crossing each other, a magnetic field can be efficiently applied to the free layer of the MTJ element by using a yoke structure. However, even if a yoke structure is not used, the above-described effects can be obtained.

Both angles θ1 and θ2 formed with the center line Ce of the MTJ element in the direction of easy magnetization and the center lines C1 and C2 of the two write lines are preferably about 45°, but not limited thereto, and may be set within a range of 0°<θ1, θ2<90°. However, when the two write lines cross each other, θ1+θ2=90°.

A cell array structure is not limited to a one-transistor and one-MTJ type, a cross-point type, and a type in which those are laminated, and the embodiment of the invention can be applied to other structures such as, for example, a ladder structure.

The two write lines are preferably perpendicular to each other. However, it suffices for those to cross each other in a range of 0°<θ3<90°. Further, it suffices for the two write lines crossing each other to be laid out linearly, and to be laid out in zigzags or in a twisted form.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetic random access memory comprising:
first and second write lines which cross each other; and
a magnetoresistive element whose center point is not overlapped onto a cross portion of the first and second write lines, wherein a center line of the magnetoresistive element in a direction of easy magnetization and center lines of the first and second write lines form a triangle.

2. The magnetic random access memory according to claim 1,
wherein one end of the magnetoresistive element in the direction of easy magnetization is overlapped onto the first write line, and the other end is overlapped onto the second write line.

3. The magnetic random access memory according to claim 1,
further comprising blocks which are stacked on a semiconductor substrate, wherein each of the blocks has the magnetoresistive element.

4. The magnetic random access memory according to claim 1,
wherein the magnetoresistive element is connected to one of the first and second write lines.

5. The magnetic random access memory according to claim 1,
wherein the magnetoresistive element is connected to both of the first and second write lines.

6. The magnetic random access memory according to claim 1,
wherein the first and second write lines are at least partly surrounded by a magnetic material.

7. A magnetic random access memory comprising:
first and second write lines which cross each other; and
a magnetoresistive element which is not overlapped onto a center point of a cross portion of the first and second write lines, wherein a center line of the magnetoresistive element in a direction of easy magnetization and center lines of the first and second write lines form a triangle.

8. The magnetic random access memory according to claim 7,
one end of the magnetoresistive element in the direction of each magnetization is overlapped onto the first write line, and the other end is overlapped onto the second write line.

9. The magnetic random access memory according to claim 7,
further comprising blocks which are stacked on a semiconductor substrate, wherein each of the blocks has the magnetoresistive element.

10. The magnetic random access memory according to claim 7,
wherein the magnetoresistive element is connected to one of the first and second write lines.

11. The magnetic random access memory according to claim 7,
wherein the magnetoresistive element is connected to both of the first and second write lines.

12. The magnetic random access memory according to claim 7,
wherein the first and second write lines are at least partly surrounded by a magnetic material.

13. A method for writing data comprising:
establishing a state in which a first write current flows in the first write line and a second write current flows in the second write line;
writing first data into the magnetoresistive element by cutting off the second write current after the first write current is cut off; and
writing second data different from the first data into the magnetoresistive element by cutting off the first write current after the second write current is cut off,
on the magnetic random access memory according to claim 1.

14. The method according to claim 13,
wherein directions of the first and second write currents are always the same whether the first data is written or the second data is written into the magnetoresistive element.

15. The method according to claim 13,
wherein a range which is controlled by one of the first and second write currents is a range less than ½ of an area or a volume of an entire free layer of the magnetoresistive element.

16. The method according to claim 13,
wherein magnetization reversal of the magnetoresistive element is prohibited in a state in which only one of the first and second write currents flows.

17. The method according to claim 13,
wherein supply of the first and second write currents are started simultaneously.

18. The method according to claim 13,
wherein the second write current is supplied after the first write current is supplied.

19. The method according to claim 13,
wherein the first write current is supplied after the second write current is supplied.

20. The method according to claim 13,
wherein the first and second data are data different from each other.
